(19) United States
(12) Patent Application Publication
(10) Pub. No.: US 2010/0258808 A1
(43) Pub. Date: Oct. 14, 2010

(54) THIN FILM TRANSISTOR AND MANUFACTURING METHOD THEREOF

(75) Inventors: Huang-Chung Cheng, Hsinchu City (TW); I-Che Lee, Taipei City (TW); Chih-Chung Chen, Taichung County (TW); Syu-Heng Lee, Taipei City (TW); Ming-Jhe Hu, Tainan County (TW); Chien-Yun Teng, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/550,412

(22) Filed: Aug. 31, 2009

(30) Foreign Application Priority Data
Apr. 9, 2009 (TW) 98111847

(51) Int. Cl. H01L 29/786; H01L 21/336

(52) U.S. Cl. 257/66; 438/157; 257/E21.412; 257/E29.288

(57) ABSTRACT

A thin film transistor and a manufacturing method thereof are provided. A bottom gate, a gate insulating layer and an amorphous semiconductor layer are formed on a substrate. The amorphous semiconductor layer has an uneven upper surface. A laser annealing process is performed on the amorphous semiconductor layer through the uneven upper layer to transform the amorphous semiconductor layer into a polycrystalline semiconductor layer having a smaller-crystallizing-section and a greater-crystallizing-section. Another gate insulating layer, an upper gate and patterned photoresist layer are formed on the polycrystalline semiconductor layer. Patterns of the upper gate and the bottom gate are defined by the same photo-mask. A source/drain is formed in the polycrystalline semiconductor layer. An etching process with etching selectivity is performed on the upper gate and the patterned photoresist layer to make a length of the upper gate shorter than that of the bottom gate.

### CROSS-REFERENCE TO RELATED APPLICATION

This application claims the priority benefit of Taiwan application serial no. 98111847, filed Apr. 9, 2009. The entirety of the above-mentioned patent application is hereby incorporated by reference herein and made a part of specification.

### BACKGROUND OF THE INVENTION

1. Field of the Invention

The present invention relates to a semiconductor device and a manufacturing method thereof, and more particularly, to a thin film transistor (TFT) and a manufacturing method thereof.

2. Description of Related Art

Most semiconductor devices require driving switches for driving the same. To give an example, an actively driven display apparatus usually incorporates a thin film transistor (TFT) as a driving switch. In addition, TFTs are generally categorized into amorphous silicon (a-Si) TFTs and low temperature poly-silicon (LTPS) TFTs according to materials adopted for making channel region thereof. Compared with the a-Si TFTs, the LTPS TFTs have low power consumption and high electron mobility, and thus receive more attention in the market.

However, in the LTPS TFTs, the distribution of the grain boundary within the channel region is mostly inconsistent, so as to cause an uneven electrical property of the devices. In other words, different numbers of grain boundaries within the channel region of the device or even different positions of the grain boundaries would result differences in the electrical properties between the LTPS TFTs, thereby affecting device efficiency.

### SUMMARY OF THE INVENTION

A thin film transistor (TFT) is provided in the present invention, in which the TFT has a characteristic of low leakage current as grains within channel region between a source and a drain are formed on predetermined positions.

A manufacturing method of a TFT is further provided in the present invention, in which grains within channel region have greater grain size.

Another manufacturing method of a TFT is provided in the present invention, in which channel region have better grain arrangements.

A manufacturing method of a TFT is provided in the present invention. Firstly, a bottom gate is formed on a substrate. Moreover, a first gate insulating layer is formed on the substrate. The first gate insulating layer covers the bottom gate and includes a first flat portion, a second flat portion, and a stair portion. The first flat portion is disposed directly above the bottom gate, the second flat portion is disposed above a portion of the substrate which is not covered by the bottom gate, and the stair portion is disposed between the first flat portion, the second flat portion, and the bottom gate. Next, an amorphous semiconductor layer is formed on the first gate insulating layer, where the amorphous semiconductor layer covers the bottom gate and the substrate, so that the amorphous semiconductor layer includes an uneven upper surface through the stair portion. Thereafter, a laser annealing process is performed to the amorphous semiconductor layer through the uneven upper surface so as to transform the amorphous semiconductor layer into a polycrystalline semiconductor layer having a smaller-crystallizing-section and a greater-crystallizing-section. The smaller-crystallizing-section corresponds to the stair portion, and the greater-crystallizing-section corresponds to the first flat portion. Moreover, a grain size in the greater-crystallizing-section is greater than that in the smaller-crystallizing-section. Afterwards, a second gate insulating layer, an upper gate, and a patterned photoresist layer are sequentially formed on the polycrystalline semiconductor layer. A pattern of the upper gate, the patterned photoresist layer, and a pattern of the aforementioned bottom gate are defined by the same photo-mask. Later, an ion implementation process is performed to the polycrystalline semiconductor layer by using the second gate insulating layer, the upper gate, and the patterned photoresist layer as a mask for forming a source and a drain in the polycrystalline semiconductor layer. Subsequently, an etching process is performed, where the etching process has an etching selectivity to the upper gate and the patterned photoresist layer, so that a length of the upper gate is shorter than a length of the bottom gate.

A TFT including a substrate, a bottom gate, a first gate insulating layer, a polycrystalline semiconductor layer, a second gate insulating layer, and an upper gate is further provided in the present invention. The bottom gate is disposed on the substrate, and the first gate insulating layer covers the bottom gate. Here, the first gate insulating layer has a first flat portion, a second flat portion, and a stair portion. The first flat portion is disposed directly above the bottom gate, the second flat portion is disposed above a portion of the substrate which is not covered by the bottom gate, and the stair portion is disposed between the first flat portion, the second flat portion, and the bottom gate. The polycrystalline semiconductor layer is disposed on the first gate insulating layer above the bottom gate. The polycrystalline semiconductor layer has a greater-crystallizing-section and a smaller-crystallizing-section. Moreover, the smaller-crystallizing-section corresponds to the stair portion, and the greater-crystallizing-section corresponds to the first flat portion. A source and a drain are disposed outside of the greater-crystallizing-section, and a grain size in the greater-crystallizing-section is greater than a grain size in the smaller-crystallizing-section. The second gate insulating layer is disposed on the polycrystalline semiconductor layer. The upper gate is disposed on the second gate insulating layer. Here, a length of the upper gate is shorter than a length of the bottom gate.

In one embodiment of the TFT and the manufacturing method of the TFT in the present invention, the length of the upper gate substantially ranges from 0.3 micrometer (μm) to 1.8 μm, and the length of the bottom gate substantially ranges from 0.5 μm to 2.0 μm.

In one embodiment of the manufacturing method of the TFT in the present invention, in the etching process, an etching selectivity ratio of the upper gate to the patterned photoresist layer substantially ranges from 23 to 25.

In one embodiment of the manufacturing method of the TFT in the present invention, a removal of the patterned photoresist layer is further included.

A manufacturing method of a TFT is further provided in the present invention. First of all, a bottom gate is formed on a substrate. Next, an insulating spacer is formed on a sidewall of the bottom gate. Moreover, a first gate insulating layer is formed on the substrate to cover the bottom gate and the insulating spacer. The first gate insulating layer includes a first flat portion, a second flat portion, and a stair portion. The first flat portion is disposed directly above the bottom gate. The second flat portion is disposed above a portion of the substrate which is not covered by the bottom gate and the insulating spacer. In addition, the stair portion is disposed between the first flat portion, the second flat portion, and the insulating spacer. Next, an amorphous semiconductor layer is formed on the first gate insulating layer, where the amorphous semiconductor layer covers the bottom gate, the insulating spacer, and the substrate, so that the amorphous semiconductor layer has an uneven upper surface through the stair portion. Thereafter, a laser annealing process is performed to the amorphous semiconductor layer through the uneven upper surface so as to transform the amorphous semiconductor layer into a polycrystalline semiconductor layer having a smaller-crystallizing-section and a greater-crystallizing-section. The smaller-crystallizing-section corresponds to the stair portion, and the greater-crystallizing-section corresponds to the first flat portion. Moreover, a grain size in the greater-crystallizing-section is greater than that in the smaller-crystallizing-section. Afterwards, a second gate insulating layer and an upper gate are sequentially formed on the polycrystalline semiconductor layer. Subsequently, an ion implementation process is performed to the polycrystalline semiconductor layer by using the second gate insulating layer and the upper gate as a mask to form a source and a drain in the polycrystalline semiconductor layer.

A TFT including a substrate, a bottom gate, an insulating spacer, a first gate insulating layer, a polycrystalline semiconductor layer, a second gate insulating layer, and an upper gate is further provided in the present invention. The bottom gate is disposed on the substrate, and the insulating spacer is disposed on a sidewall of the bottom gate. Furthermore, the first gate insulating layer is disposed on the substrate and covers the bottom gate and the insulating spacer. The first gate insulating layer includes a first flat portion, a second flat portion, and a stair portion. The first flat portion is disposed directly above the bottom gate. The second flat portion is disposed above a portion of the substrate which is not covered by the bottom gate and the insulating spacer. In addition, the stair portion is disposed between the first flat portion, the second flat portion, and the insulating spacer. The polycrystalline semiconductor layer is disposed on the first gate insulating layer above the bottom gate. The polycrystalline semiconductor layer has a greater-crystallizing-section and a smaller-crystallizing-section. Moreover, the smaller-crystallizing-section corresponds to the stair portion, and the greater-crystallizing-section corresponds to the first flat portion. Also, a source and a drain are disposed outside of the greater-crystallizing-section. The second gate insulating layer is disposed on the polycrystalline semiconductor layer, and a grain size in the greater-crystallizing-section is greater than that in the smaller-crystallizing-section. The upper gate is disposed on the second gate insulating layer.

In one embodiment of the two manufacturing methods of the TFT in the present invention, after the laser annealing process is performed through the uneven upper surface, a grain size in the greater-crystallizing-section is substantially greater than 0.5 μm.

In one embodiment of the two TFTs in the present invention, a grain size in the greater-crystallizing-section is substantially greater than 0.5 μm.

In one embodiment of the two manufacturing methods of the TFT in the present invention, the following steps are further included. Firstly, a passivation layer is formed on the first gate insulating layer, the polycrystalline semiconductor layer, and the upper gate. Next, the passivation layer is patterned to form a plurality of contact openings corresponding to the source, the drain, and the upper gate in the passivation layer. Afterwards, a plurality of contact conductors, which is electrically connected to the source, the drain, and the upper gate, is formed in the contact openings.

In one embodiment of the two TFTs in the present invention, the TFT further includes a passivation layer and a plurality of contact conductors. The passivation layer has a plurality of contact openings corresponding to the source, the drain, and the upper gate. The contact conductors are formed in the contact openings and electrically connected to the source, the drain, and the upper gate.

By using the manufacturing method of the TFT in the present invention, the TFT of the present invention is formed, where the TFT of the present invention has dual gates. Besides, the channel region between the source and the drain of the TFT in the present invention have greater grain size and better grain arrangement. Overall, the TFT of the present invention has the advantage of low leakage current.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a partial cross-sectional view of a thin film transistor (TFT) according to a first embodiment of the present invention.

FIGS. 2A-2H are partial cross-sectional views showing a flowchart of manufacturing the TFT according to the first embodiment of the present invention.

FIG. 2E′ is a partial top view of the TFT in FIG. 2E.

FIG. 2I is a partial cross-sectional view showing a formation of a passivation layer and contact conductors according to the first embodiment of the present invention.

FIG. 3 is a partial cross-sectional view of a TFT according to a second embodiment of the present invention.

FIGS. 4A through 4G are partial cross-sectional views showing a flowchart of manufacturing the TFT according to the second embodiment of the present invention.

FIG. 4H is a partial cross-sectional view showing a formation of a passivation layer and contact conductors according to the second embodiment of the present invention.

### DESCRIPTION OF EMBODIMENTS

### The First Embodiment

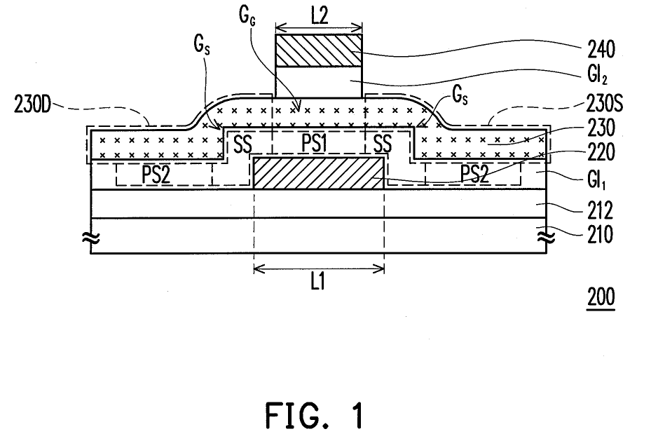

FIG. 1 is a partial cross-sectional view of a thin film transistor (TFT) according to a first embodiment of the present invention. Referring to FIG. 1, a TFT 200 of the present embodiment includes a substrate 210, a bottom gate 220, a first gate insulating layer GI₁, a polycrystalline semiconductor layer 230, a second gate insulating layer GI₂, and an upper gate 240. The bottom gate 220 is disposed on the substrate 210, and the first gate insulating layer GI₁ covers the bottom gate 220. The polycrystalline semiconductor layer 230 is disposed on the first gate insulating layer GI₁ which is above the bottom gate 220. The polycrystalline semiconductor layer 230 has a source 230S and a drain 230D. The second gate insulating layer GI₂ is disposed on the polycrystalline semiconductor layer 230, and the upper gate 240 is disposed on the second gate insulating layer GI₂. Moreover, the TFT 200 of the present embodiment further includes a buffer layer 212 disposed between the substrate 210 and the bottom gate 220, so as to isolate the substrate 210 and the bottom gate 220.

It should be noted that in the present embodiment, a length L1 of the bottom gate 220 is different from a length L2 of the upper gate 240. To be more specific, the length L2 of the upper gate 240 in the present embodiment is shorter than the length L1 of the bottom gate 220. Such a structure facilitates the reduction in leakage currents of the TFT 200. In addition, in the present embodiment, the length L1 of the bottom gate 220 substantially ranges from 0.5 micrometers (μm) to 2.0 μm while the length L2 of the upper gate 240 substantially ranges from 0.3 μm to 1.8 μm.

From another perspective, the polycrystalline semiconductor layer 230 of the present embodiment is divided into a greater-crystallizing-section G_{G} and a smaller-crystallizing-section G_{S} according to grain sizes. Here, a grain size in the greater-crystallizing-section G_{G} is greater than that in the smaller-crystallizing-section G_{S}. As shown in FIG. 1, the smaller-crystallizing-section G_{S} corresponds to a stair portion SS and the greater-crystallizing-section G_{G} corresponds to a first flat portion PS1. Moreover, the source 230S and the drain 230D are disposed outside of the greater-crystallizing-section G_{G}.

Furthermore, when the TFT 200 is conductive, channel region is formed between the source 230S and the drain 230D, and a driving current flows from the source 230S to the drain 230D via the channel region. Conventionally, grain boundaries that are perpendicular to a direction of the driving current are present in the polycrystalline semiconductor layer. These grain boundaries obstruct the driving current in the channel region, and the degree of obstruction elevates as the number of grain boundaries increases. In the present embodiment, grains in the polycrystalline semiconductor layer 230, which are disposed above the bottom gate 220, have greater grain size and therefore less number of grain boundaries. Consequently, the obstruction of the current in the channel region can be reduced, thereby increasing a carrier mobility of the TFT 200.

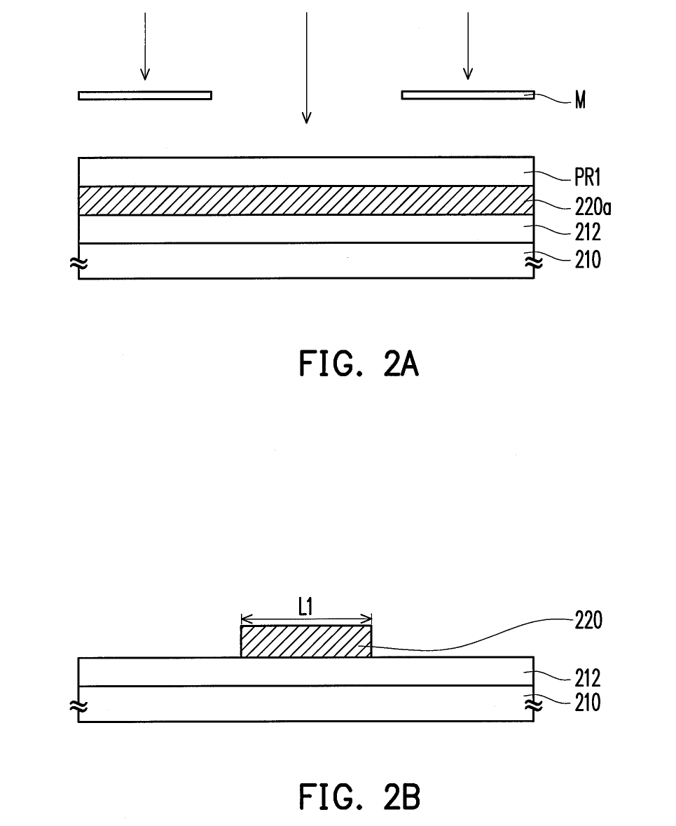

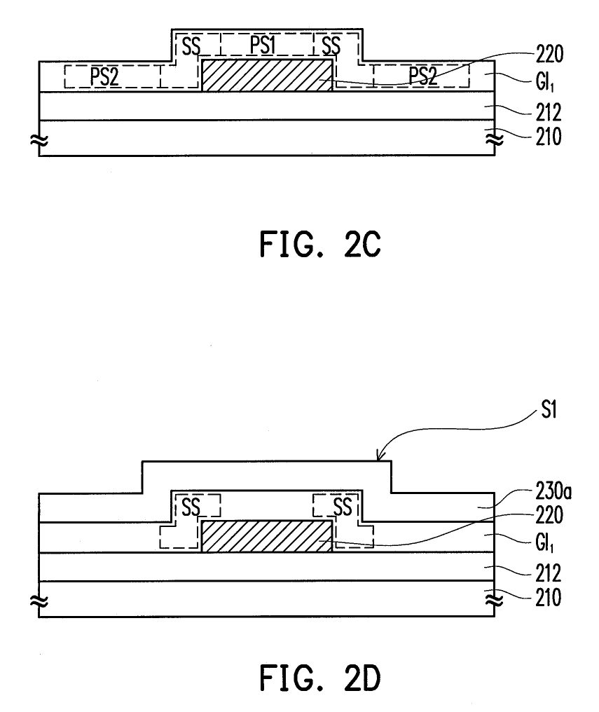

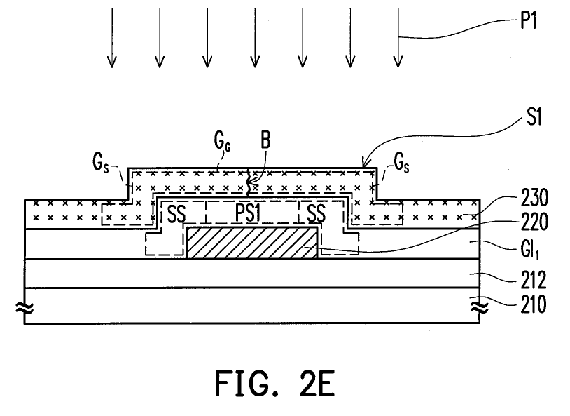

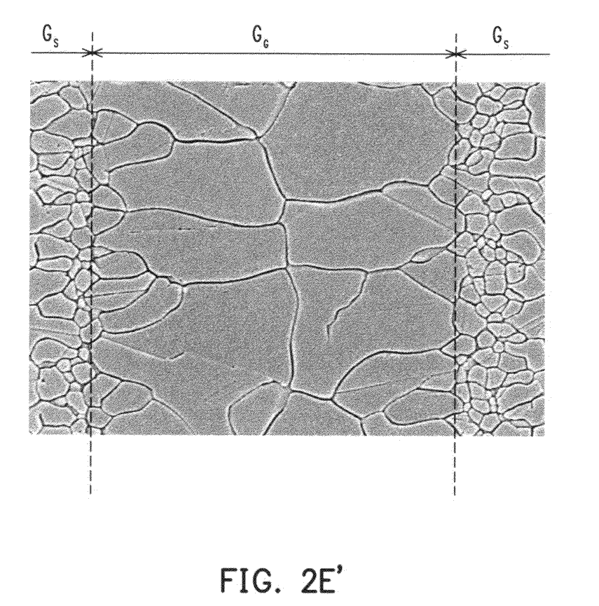

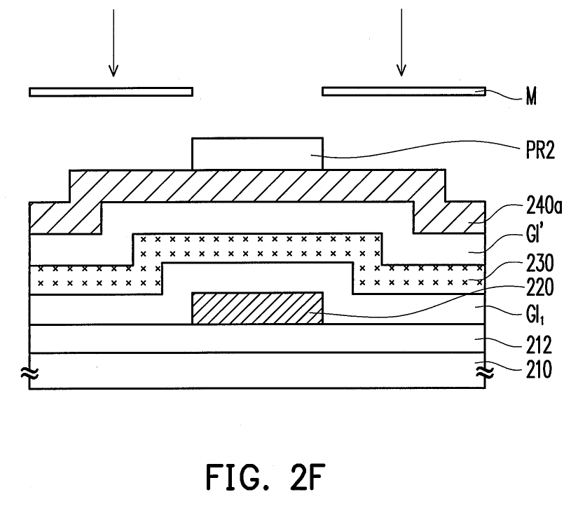

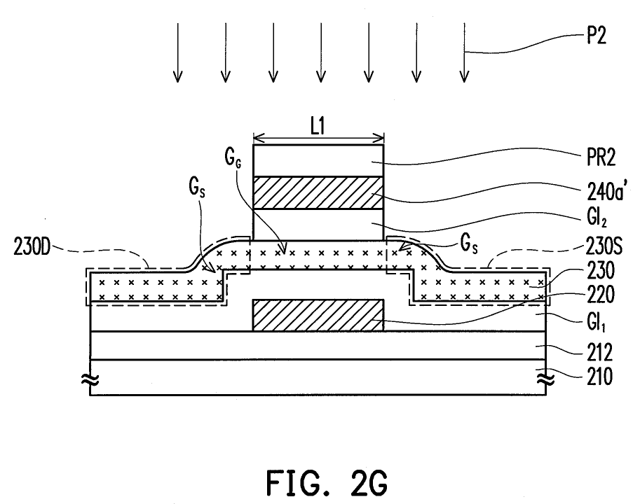

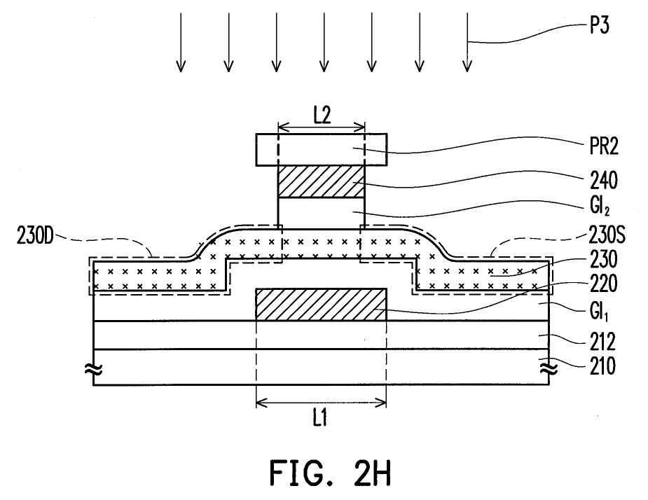

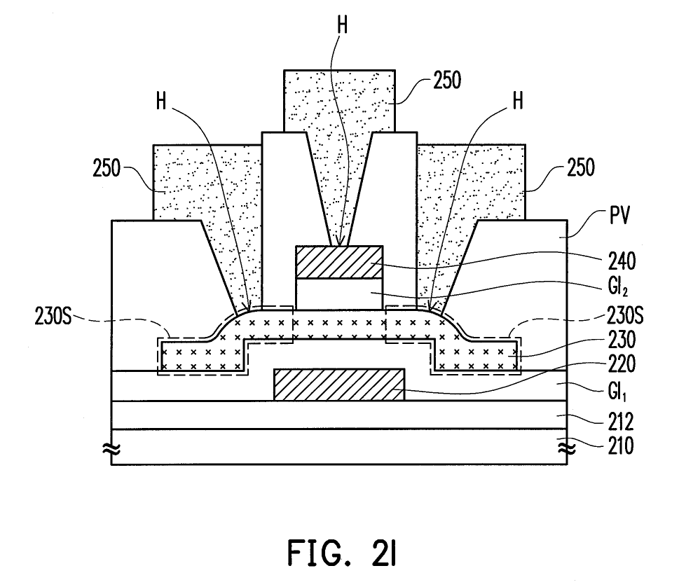

Based on the TFT 200 aforementioned, the present embodiment further provides a manufacturing method of the TFT 200. FIGS. 2A-2H are partial cross-sectional views showing a flowchart of manufacturing the TFT in the first embodiment of the present invention. Firstly, referring to FIG. 2A, a first doping semiconductor layer 220a and a photoresist material layer PR1 are sequentially formed on a substrate 210. Here, a material of the substrate 210 is a rigid heat-resistant material such as quartz, glass, silicon, and the like. Moreover, the first doping semiconductor layer 220a is, for example, doped with amorphous silicon (a-Si). A method of forming the first doping semiconductor layer 220a is low pressure chemical vapor deposition (LPCVD) or other suitable thin film deposition techniques, for instance. It should be illustrated that the photoresist material layer PR1 in FIG. 2A is a positive photoresist layer, for example, but the present invention is not limited thereto.

Thereafter, a photo-mask M is adopted to perform a photolithographic process for patterning the photoresist material layer PR1. The patterned photoresist material layer (not shown) is used as a mask to perform an etching process to the first doping semiconductor layer 220a for forming a bottom gate 220 as shown in FIG. 2B. Herein, a length of the bottom gate 220 is L1. However, in the present embodiment, before the bottom gate 220 is formed on the substrate 210, a buffer layer 212 is formed on the substrate 210 by using a thermal oxidation method. Here, a material of the buffer layer 212 is silicon dioxide, for example.

Furthermore, referring to FIG. 2C, a first gate insulating layer GI₁ is formed on the substrate 210. The first gate insulating layer GI₁ covers the bottom gate 220. In the present embodiment, the first gate insulating layer GI₁ is entirely formed on the substrate 210, for instance. Besides, a material of the first gate insulating layer GI₁ is, for example, tetra-ethyl-ortho-silicate (TEOS) or other dielectric materials. On the other hand, a method of forming the first gate insulating layer GI₁ is a chemical vapor deposition (CVD) or other suitable thin film deposition techniques, for instance.

As aforementioned, the first gate insulating layer GI₁ of the present embodiment has a first flat portion PS1, a second flat portion PS2, and a stair portion SS. The first flat portion PS1 is disposed directly above the bottom gate 220. The second flat portion PS2 is disposed above a portion of the substrate 210 which is not covered by the bottom gate 220. Moreover, the stair portion is disposed between the first flat portion PS1, the second flat portion PS2, and the bottom gate 220. It should be noted that the stair portion SS of the present embodiment facilitates the formation of the polycrystalline semiconductor layer with greater grain size in the following manufacturing process (details thereof are illustrated later).

Next, referring to FIG. 2D, an amorphous semiconductor layer 230a is formed on the first gate insulating layer GI₁ which is above the bottom gate 220. A method of forming the amorphous semiconductor layer 230a is, for example, LPCVD or other suitable thin film deposition techniques. In addition, the amorphous semiconductor layer 230a of the present embodiment is a material of amorphous-silicon, group III-V compound semiconductors, group II-VI compound semiconductors, group I-VII compound semiconductors, and the like. As shown in FIG. 2D, the amorphous semiconductor layer 230a of the present embodiment conformably covers the bottom gate 220 and the substrate 210. Therefore, the amorphous semiconductor layer 230a has an uneven upper surface Si through the stair portion SS.

Thereafter, referring to FIG. 2D and FIG. 2E simultaneously, a laser annealing process P1 is performed to the amorphous semiconductor layer 230a through the uneven upper surface S1 so as to transform the amorphous semiconductor layer 230a into a polycrystalline semiconductor layer 230 having a smaller-crystallizing-section G_{S} and a greater-crystallizing-section G_{G}. The smaller-crystallizing-section G_{S} corresponds to the stair portion SS and the greater-crystallizing-section G_{G} corresponds to the first flat portion PS1. Moreover, a grain size in the greater-crystallizing-section G_{G} is greater than that in the smaller-crystallizing-section G_{S}. In the present embodiment, the laser annealing process P1 is performed with techniques such as an excimer laser, a continuous wave (CW) laser, or a carbon dioxide laser, and so on. Besides, in the present embodiment, the manufacture of the polycrystalline semiconductor layer 230 is accomplished under a low-temperature environment. In other words, the polycrystalline semiconductor layer 230 is a low-temperature polycrystalline semiconductor layer.

As aforementioned, in the present embodiment, the laser annealing process P1 is performed to the amorphous semiconductor layer 230a through the uneven upper surface S1, so that the amorphous semiconductor layer 230a crystallizes and forms a greater-crystallizing-section G_{G} with greater grain size and a smaller-crystallizing-section G_{S} with smaller grain size. In the present embodiment, the grain size in the greater-crystallizing-section G_{G} of the polycrystalline semiconductor layer 230 is greater than 0.5 μm, and generally ranges from 0.5 μm to 1 μm. In one embodiment, the grain size in the greater-crystallizing-section G_{G} is greater than 1 μm.

Referring to FIG. 2E and FIG. 2E′ simultaneously, as illustrated above, grains in the polycrystalline semiconductor layer 230 of the present invention have greater grain size. Hence, the number of grains in the polycrystalline semiconductor layer 230 above the bottom gate 220 is dramatically reduced, such that the grain boundaries between the grains are reduced as well. In one embodiment, the polycrystalline semiconductor layer 230 above the bottom gate 220 merely has a primary grain boundary B.

Afterwards, referring to FIG. 2F, a second gate insulating material layer GI', a second doping semiconductor layer 240a, and a photoresist material layer (not shown) are entirely formed on the polycrystalline semiconductor layer 230 in sequence. Here, a material of the second gate insulating material layer GI' is TEOS or other suitable dielectric materials, for example. Moreover, the second doping semiconductor layer 240a is, for example, doped with a-Si. A method of forming the second doping semiconductor layer 240a is LPCVD or other suitable thin film deposition techniques, for instance. It should be illustrated that the photoresist material layer in FIG. 2F is a positive photoresist layer, for example, but the present invention is not limited thereto. Subsequently, the photo-mask M is utilized to perform the photolithographic process for forming a patterned photoresist layer PR2. The patterned photoresist layer PR2 is used as a mask to pattern the second gate insulating material layer GI′ and the second doping semiconductor layer 240a so as to form a second gate insulating layer GI₂ and a patterned second doping semiconductor layer 240a′ on the polycrystalline semiconductor layer 230, as illustrated in FIG. 2G.

It should be noted that in the present embodiment, the photo-mask M for forming a pattern of the bottom gate 220 is adopted to form the patterned photoresist layer PR2 and the patterned second doping semiconductor layer 240a′. In other words, in the present embodiment, patterns of the patterned second doping semiconductor layer 240a′, the patterned photoresist layer PR2, and the bottom gate 220 are defined by the same photo-mask M. At this time, the lengths of the bottom gate 220 and the patterned second doping semiconductor layer 240a′ are both L1.

Referring to FIG. 2G, an ion implementation process P2 is performed to the polycrystalline semiconductor layer 230 by using the second gate insulating layer GI₂, the patterned second doping semiconductor layer 240a′, and the patterned photoresist layer PR2 as the mask, so as to form a source 230S and a drain 230D in the polycrystalline semiconductor layer 230. As shown in FIG. 2G, channel region between the source 230S and the drain 230D is located within the greater-crystallizing-section G_{G}, thereby having greater grain size.

Thereafter, referring to FIG. 2H, an etching process P3 is performed. Here, the etching process P3 is, for example, a wet etching process with high etching selectivity ratio. Specifically, referring to FIG. 2G and FIG. 2H simultaneously, the etching process P3 in the present embodiment has an etching selectivity to the patterned second doping semiconductor layer 240a′ and the patterned photoresist layer PR2. Here, the etching selectivity ratio of the second doping semiconductor layer 240a′ to the patterned photoresist layer PR2 generally ranges from 23 to 25. Hence, the upper gate 240 with the length shorter than L1 can be formed. Up to this point, the process of manufacturing the TFT 200 having dual gates 200 and 240 in the present embodiment is generally completed. Here, the length L2 of the upper gate 240 is shorter than the length L1 of the bottom gate 220 in the TFT 200.

The framework of the TFT 200 and the manufacturing method thereof in the present embodiment are illustrated above. In practice, a plurality of TFTs 200 is generally manufactured so as to be incorporated into actual products. Hence, the polycrystalline semiconductor layers 230 in these TFTs 200 are further patterned to form a plurality of island-shaped polycrystalline semiconductor layers that are not connected to each other, thereby isolating the TFTs 200.

In the present embodiment, a passivation layer (the details thereof are illustrated later) and a plurality of contact conductors (the details thereof are illustrated later) which is electrically connected to the source 230S, the drain 230D, and the upper gate 240 are further formed. Besides, the patterned photoresist layer PR2 (shown in FIG. 2H) can be removed before the formation of the passivation layer and the contact conductors. As illustrated in FIG. 2I, a passivation layer PV is formed on the first gate insulating layer GI₁, the polycrystalline semiconductor layer 230, and the upper gate 240. In the present embodiment, a material of the passivation layer PV is silicon dioxide (SiO₂), silicon nitride (Si₃N₄), or other suitable dielectric materials, and a method of forming the passivation layer PV is plasma enhanced chemical vapor deposition (PECVD), for example. Next, the passivation layer PV is patterned to form a plurality of contact openings H corresponding to the source 230S, the drain 230D, and the upper gate 240 in the passivation layer PV. Afterwards, a plurality of contact conductors 250, which is electrically connected to the source 230S, the drain 230D, and the upper gate 240, is formed in the contact openings H. In the present embodiment, a material of the contact conductors 250 is aluminum, for example, but the present invention is not limited thereto.

### The Second Embodiment

The concept to be illustrated in the present embodiment is similar to that of the first embodiment. The main difference between the two is that in the present embodiment, a length of a bottom gate of a TFT is generally similar to that of an upper gate, but a sidewall of the bottom gate includes an insulating spacer.

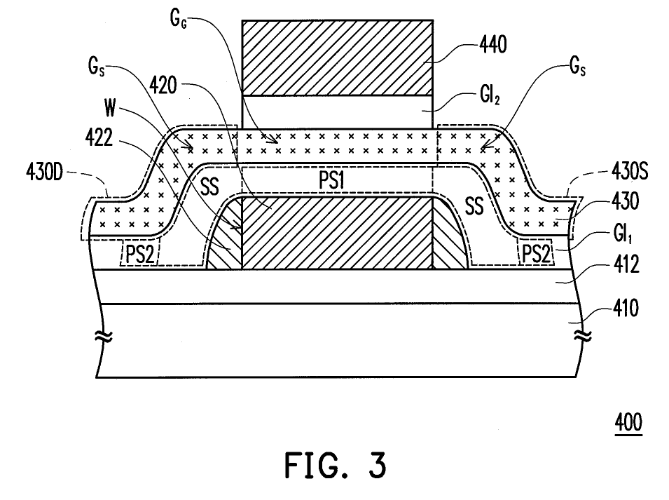

FIG. 3 is a partial cross-sectional view of a TFT according to a second embodiment of the present invention. Referring to FIG. 3, a TFT 400 of the present embodiment includes a substrate 410, a bottom gate 420, an insulating spacer 422, a first gate insulating layer GI₁, a polycrystalline semiconductor layer 430, a second gate insulating layer GI₂, and an upper gate 440. The bottom gate 420, the insulating spacer 422, and the first gate insulating layer GI₁ are disposed on the substrate 410. The insulating spacer 422 is disposed on a sidewall W of the bottom gate 420. The first gate insulating layer GI₁ covers the bottom gate 420 and the insulating spacer 422. The polycrystalline semiconductor layer 430 is disposed on the first gate insulating layer GI₁, which is above the bottom gate 420. The polycrystalline semiconductor layer 430 has a source 430S and a drain 430D. The second gate insulating layer GI₂ is disposed on the polycrystalline semiconductor layer 430, and the upper gate 440 is disposed on the second gate insulating layer GI₂. Moreover, in the TFT 400 of the present invention, a buffer layer 412 is further disposed between the substrate 410 and the bottom gate 420.

From another perspective, the polycrystalline semiconductor layer 430 of the present embodiment is divided into a greater-crystallizing-section G_{G} and a smaller-crystallizing-section G_{S} according to grain sizes. Here, a grain size in the greater-crystallizing-section G_{G} is greater than that in the smaller-crystallizing-section G_{S}. As shown in FIG. 3, the smaller-crystallizing-section G_{S} corresponds to a stair portion SS, and the greater-crystallizing-section G_{G} corresponds to a first flat portion PS1. Moreover, the source 430S and the drain 430D are disposed outside of the greater-crystallizing-section G_{G}.

As illustrated above, the insulating wall 422 is formed beside the sidewall W of the bottom gate 420 in the present embodiment. Such a structure allows the polycrystalline semiconductor layer 430 above the bottom gate 420 to have a better grain characteristic, thereby reducing a leakage current of the TFT 400. In details, in the present embodiment, grains in the polycrystalline semiconductor layer 430, which is disposed above the bottom gate 420, have a greater grain size and therefore less number of grain boundaries. Hence, the obstruction of the current in channel region is reduced, thereby increasing a carrier mobility of the TFT 400.

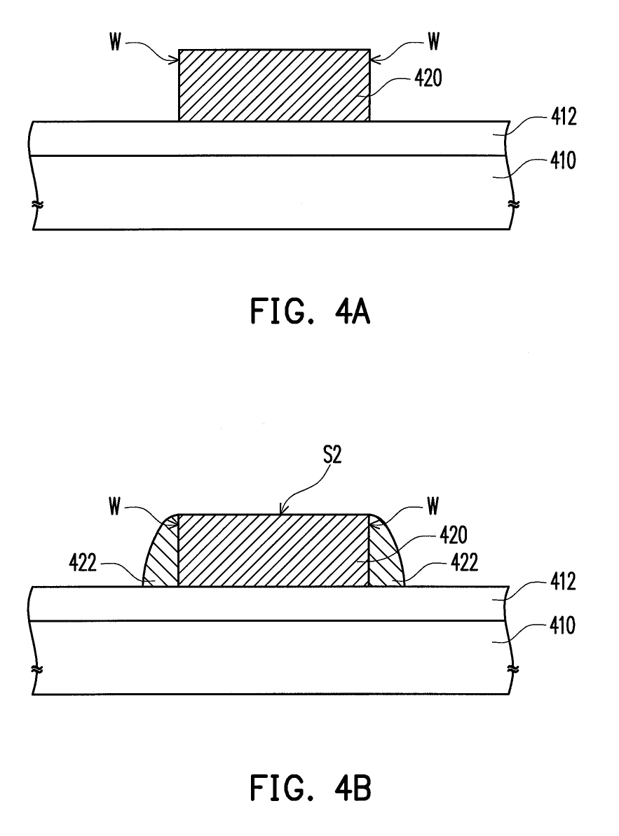

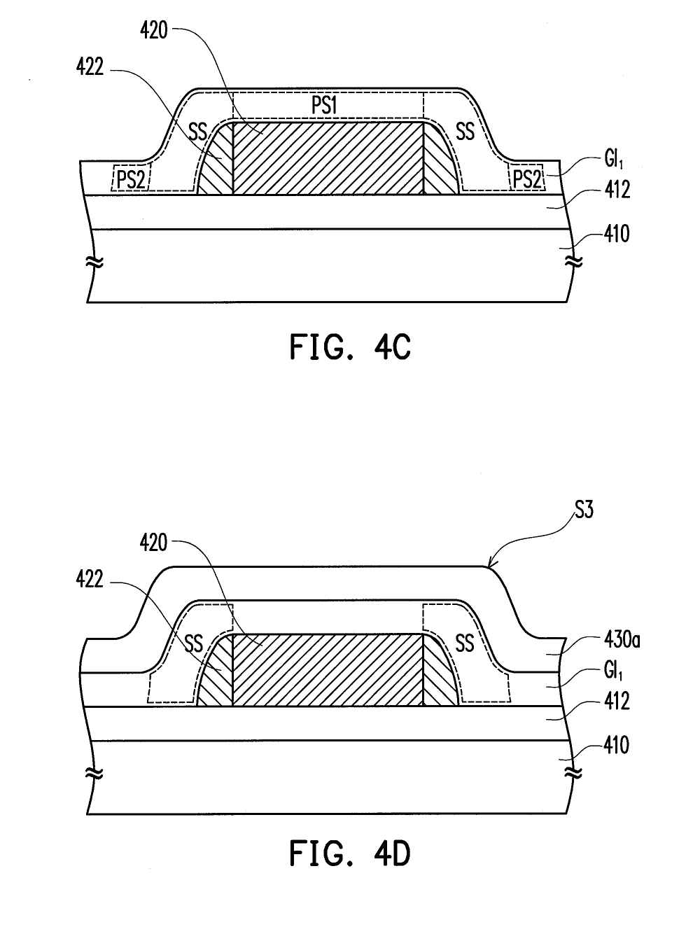

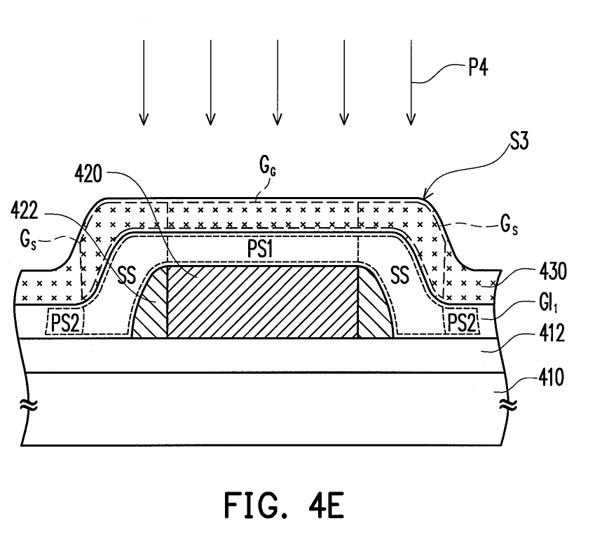

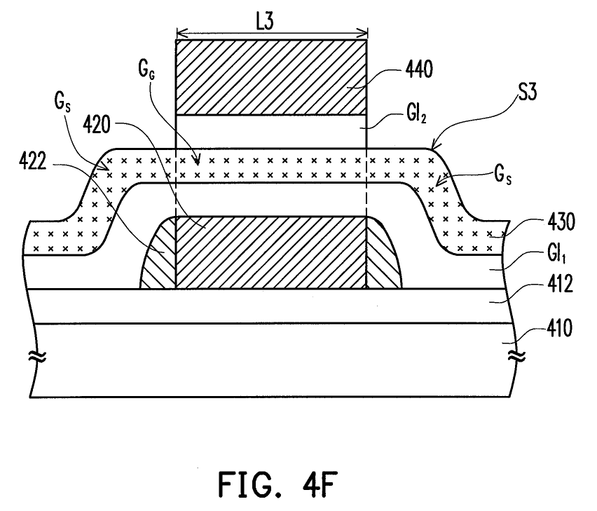

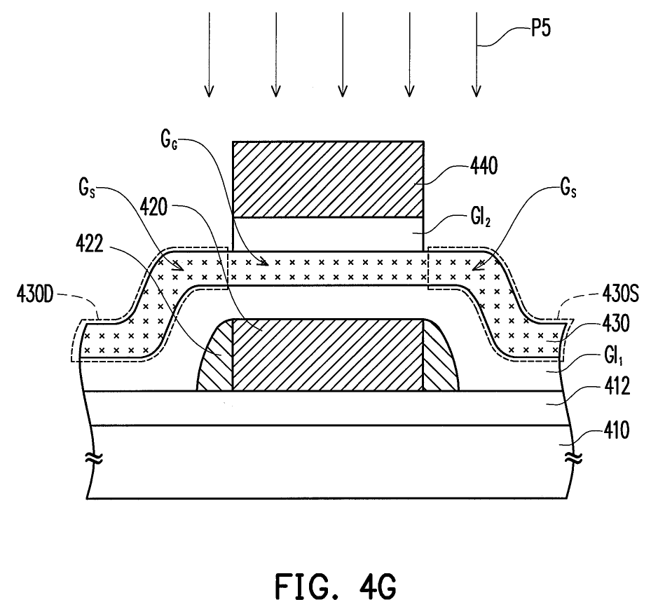

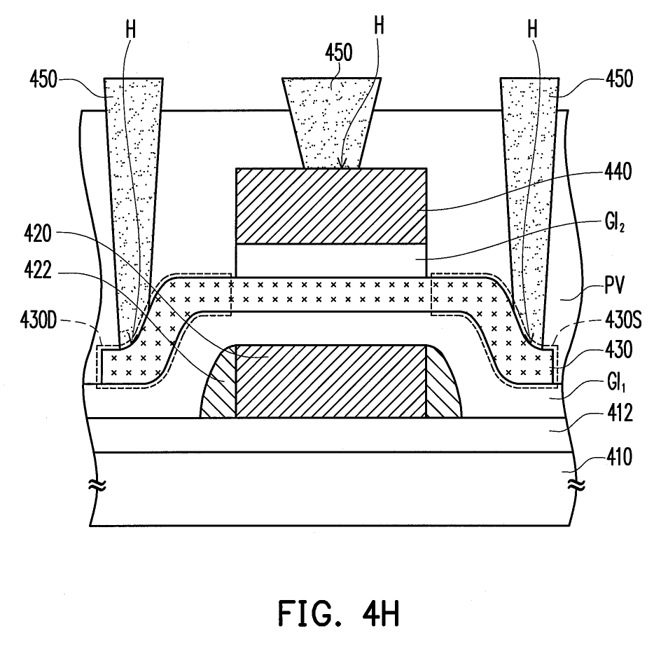

According to the TFT 400 aforementioned, the present embodiment further provides a manufacturing method of the TFT 400. FIGS. 4A to 4G are partial cross-sectional views showing a flowchart of manufacturing the TFT according to the second embodiment of the present invention. Firstly, referring to FIG. 4A, a bottom gate 420 is formed on a substrate 410. Here, the bottom gate 420 includes a sidewall W. In the present embodiment, a method of forming the bottom gate 420, for instance, is to form a first poly-silicon layer (not shown) on the substrate 410 and then pattern the first poly-silicon layer for forming the bottom gate 420. In addition, in the present embodiment, before the bottom gate 420 is formed on the substrate 410, a buffer layer 412 is formed on the substrate 410 by using a thermal oxidation method. Here, a material of the buffer layer 412 is silicon oxide, for example.

Next, referring to FIG. 4B, an insulating spacer 422 is formed on the sidewall W of the bottom gate 420. In the present embodiment, a method of forming the insulating spacer 422 is to form an oxide layer (not shown) entirely on the substrate 410 and the bottom gate 420, for instance. Next, an anisotropic dry etching process is performed to the oxide layer to remove a portion of the oxide layer on an upper surface S2 of the bottom gate 420 and retain a portion of the oxide layer beside the sidewall W of the bottom gate 420.

Furthermore, referring to FIG. 4C, a first gate insulating layer GI₁ is formed on the substrate 410. The first gate insulating layer GI₁ covers the bottom gate 420 and the insulating spacer 422. However, a material and a formation of the first gate insulating layer GI₁ in the present embodiment can refer to FIG. 2C in the first embodiment and the description thereof, and are thus not illustrated herein.

As aforementioned, the first gate insulating layer GI₁ of the present embodiment has a first flat portion PS1, a second flat portion PS2, and a stair portion SS. The first flat portion PS1 is disposed directly above the bottom gate 420. The second flat portion PS2 is disposed above a portion of the substrate 410 which is not covered by the bottom gate 420 and the insulating spacer 422. Moreover, the stair portion SS is disposed between the first flat portion PS1, the second flat portion PS2, and the insulating spacer 422. It should be noted that the stair portion SS of the present embodiment facilitates a formation of the polycrystalline semiconductor layer with greater grain size in the following manufacturing process (the details are illustrated later).

Subsequently, referring to FIG. 4D, an amorphous semiconductor layer 430a is formed on the first gate insulating layer GI₁, where the amorphous semiconductor layer 430a conformably covers the bottom gate 420, the insulating spacer 422, and the substrate 410, so that the amorphous semiconductor layer 430a has an uneven upper surface S3 through the stair portion SS. Nevertheless, a material and a formation of the amorphous semiconductor layer 430a in the present embodiment can refer to FIG. 2D in the first embodiment and the description thereof, and are thus not illustrated herein.

Thereafter, referring to FIG. 4D and FIG. 4E simultaneously, a laser annealing process P4 is performed to the amorphous semiconductor layer 430a through the uneven upper surface S3 so as to transform the amorphous semiconductor layer 430a into a polycrystalline semiconductor layer 430 having a smaller-crystallizing-section G_{S} and a greater-crystallizing-section G_{G}. The smaller-crystallizing-section G_{S} corresponds to the stair portion SS, and the greater-crystallizing-section G_{G} corresponds to the first flat portion PS1. Moreover, a grain size in the greater-crystallizing-section G_{G} is greater than that in the smaller-crystallizing-section G_{S}. However, a method of forming the polycrystalline semiconductor layer 430 in the present embodiment can refer to FIG. 2D, FIG. 2E in the first embodiment and the descriptions thereof, and are thus not illustrated herein.

As mentioned above, in the present embodiment, the laser annealing process P4 is performed to the amorphous semiconductor layer 430a through the uneven upper surface S3 for forming the greater-crystallizing-section G_{G} with greater grain size and the smaller-crystallizing-section G_{S} with smaller grain size. In the present embodiment, a grain size in the polycrystalline semiconductor layer 430 is substantially greater than 0.5 μm. In one embodiment, the grain size in the greater-crystallizing-section G_{G} substantially ranges from 0.5 μm to 1 μm.

Thereafter, referring to FIG. 4F, a second gate insulating layer GI₂ and an upper gate 440 are sequentially formed on the polycrystalline semiconductor layer 430. A method of forming the second gate insulating layer GI₂ and the upper gate 440 in the present embodiment is, for example, to entirely form a second gate insulating material layer (not shown) and a second poly-silicon layer (not shown) on the polycrystalline semiconductor layer 430 sequentially. Afterwards, a photolithographic process and an etching process are used to pattern the second gate insulating material layer and the second poly-silicon layer. Furthermore, the upper gate 440 and the bottom gate 420 of the present embodiment have a same length L3, for example. Thus, in the present embodiment, a pattern of the upper gate 440 and a pattern of the bottom gate 420 are defined by the same photo-mask.

Next, referring to FIG. 4G, an ion implementation process P5 is performed to the polycrystalline semiconductor layer 430 by using the second gate insulating layer GI₂ and the upper gate 440 as a mask to form a source 430S and a drain 430D in the polycrystalline semiconductor layer 430. As shown in FIG. 4G, channel region between the source 430S and the drain 430D is located within the greater-crystallizing-section G_{G}, thereby having greater grain size.

In practice, the polycrystalline semiconductor layer 430 can be further patterned to form a plurality of island-shaped polycrystalline semiconductor layers that is not connected to each other.

After that, as illustrated in FIG. 4H, a passivation layer PV and a plurality of contact conductors 450 which is electrically connected to the source 430S, the drain 430D, and the upper gate 440 are further formed in the present embodiment. Here, the passivation layer PV includes a plurality of contact openings H corresponding to the source 430S, the drain 430D, and the upper gate 440. Moreover, the contact conductors 450 are filled into the contact openings H. Nevertheless, materials and formations of the passivation layer PV and the contact conductors 450 in the present embodiment can refer to FIG. 2I in the first embodiment and the description thereof, and are thus not illustrated herein.

Besides, it should be illustrated that the present invention is not limited to all of the embodiments aforementioned. To give an example, in another embodiment, the two embodiments aforementioned can be further combined to form the TFT with the length of the upper gate shorter than the length of the bottom gate and having two structures of the insulating spacers beside the bottom gate.

In summary, the TFT of the present invention has characteristics of having dual gates and having greater grain size in the channel region, and consequently has advantages of low current, high carrier mobility, and the like. In addition, in the manufacturing method of the TFT in the present invention, grains are formed on the predetermined positions in the channel region, so that the channel region has a better grain arrangement. Overall, by using the manufacturing method of the TFT in the present invention, the TFT with a better device characteristic is manufactured.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A manufacturing method of a thin film transistor (TFT), comprising:
forming a bottom gate on a substrate, wherein a pattern of the bottom gate is defined by a photo-mask;
forming a first gate insulating layer on the substrate to cover the bottom gate, wherein the first gate insulating layer has a first flat portion, a second flat portion, and a stair portion, the first flat portion is disposed directly above the bottom gate, the second flat portion is disposed above a portion of the substrate which is not covered by the bottom gate, and the stair portion is disposed between the first flat portion, the second flat portion and the bottom gate;
forming an amorphous semiconductor layer on the first gate insulating layer, wherein the amorphous semiconductor layer covers the bottom gate and the substrate, so that the amorphous semiconductor layer comprises an uneven upper surface through the stair portion;
performing a laser annealing process to the amorphous semiconductor layer through the uneven upper surface so as to transform the amorphous semiconductor layer into a polycrystalline semiconductor layer having a smaller-crystallizing-section and a greater-crystallizing-section, wherein the smaller-crystallizing-section corresponds to the stair portion, the greater-crystallizing-section corresponds to the first flat portion, and a grain size in the greater-crystallizing-section is greater than a grain size in the smaller-crystallizing-section;
sequentially forming a second gate insulating layer, an upper gate, and a patterned photoresist layer, wherein a pattern of the upper gate and the patterned photoresist layer are defined by the photo-mask;
performing an ion implementation process to the polycrystalline semiconductor layer by using the second gate insulating layer, the upper gate, and the patterned photoresist layer as a mask to form a source and a drain in the polycrystalline semiconductor layer; and
performing an etching process, wherein the etching process has an etching selectivity to the upper gate and the patterned photoresist layer, so that a length of the upper gate is shorter than a length of the bottom gate.

2. The manufacturing method of the TFT as claimed in claim 1, wherein after the laser annealing process is performed through the uneven upper surface, the grain size in the greater-crystallizing-section is substantially greater than 0.5 micrometers (μm).

3. The manufacturing method of the TFT as claimed in claim 1, wherein the length of the upper gate substantially ranges from 0.3 μm to 1.8 μm, and the length of the bottom gate substantially ranges from 0.5 μm to 2.0 μm.

4. The manufacturing method of the TFT as claimed in claim 1, wherein in the etching process, an etching selectivity ratio of the upper gate to the patterned photoresist layer substantially ranges from 23 to 25.

5. The manufacturing method of the TFT as claimed in claim 1, further comprising:
removing the patterned photoresist layer.

6. The manufacturing method of the TFT as claimed in claim 1, further comprising:
forming a passivation layer on the first gate insulating layer, the polycrystalline semiconductor layer, and the upper gate;
patterning the passivation layer, so as to form a plurality of contact openings corresponding to the source, the drain, and the upper gate in the passivation layer; and
forming a plurality of contact conductors electrically connected to the source, the drain, and the upper gate in the plurality of contact openings.

7. A manufacturing method of a TFT, comprising:
forming a bottom gate on a substrate;
forming an insulating spacer on a sidewall of the bottom gate;
forming a first gate insulating layer on the substrate to cover the bottom gate and the insulating spacer, wherein the first gate insulating layer has a first flat portion, a second flat portion, and a stair portion, the first flat portion is disposed directly above the bottom gate, the second flat portion is disposed above a portion of the substrate which is not covered by the bottom gate and the insulating spacer, and the stair portion is disposed between the first flat portion, the second flat portion and the insulating spacer;
forming an amorphous semiconductor layer on the first gate insulating layer, wherein the amorphous semiconductor layer covers the bottom gate, the insulating spacer, and the substrate, so that the amorphous semiconductor layer comprises an uneven upper surface through the stair portion;
performing a laser annealing process to the amorphous semiconductor layer through the uneven upper surface so as to transform the amorphous semiconductor layer into a polycrystalline semiconductor layer having a smaller-crystallizing-section and a greater-crystallizing-section, wherein the smaller-crystallizing-section corresponds to the stair portion, the greater-crystallizing-section corresponds to the first flat portion, and a grain size in the greater-crystallizing-section is greater than a grain size in the smaller-crystallizing-section;
sequentially forming a second gate insulating layer and an upper gate on the polycrystalline semiconductor layer; and
performing an ion implementation process to the polycrystalline semiconductor layer by using the second gate insulating layer and the upper gate as a mask to form a source and a drain in the polycrystalline semiconductor layer.

8. The manufacturing method of the TFT as claimed in claim 7, wherein after the laser annealing process is performed through the uneven upper surface, the grain size in the greater-crystallizing-section is substantially greater than 0.5 μm.

9. The manufacturing method of the TFT as claimed in claim 7, further comprising:
forming a passivation layer on the first gate insulating layer, the polycrystalline semiconductor layer, and the upper gate;
patterning the passivation layer, so as to form a plurality of contact openings corresponding to the source, the drain, and the upper gate in the passivation layer; and
forming a plurality of contact conductors electrically connected to the source, the drain, and the upper gate in the plurality of contact openings.

10. A TFT, comprising:
a substrate;
a bottom gate, disposed on the substrate;
a first gate insulating layer covering the bottom gate, wherein the first gate insulating layer has a first flat portion, a second flat portion, and a stair portion, the first flat portion is disposed directly above the bottom gate, the second flat portion is disposed above a portion of the substrate which is not covered by the bottom gate, and the stair portion is disposed between the first flat portion, the second flat portion, and the bottom gate;
a polycrystalline semiconductor layer, disposed on the first gate insulating layer above the bottom gate, having a greater-crystallizing-section and a smaller-crystallizing-section, wherein the smaller-crystallizing-section corresponds to the stair portion, the greater-crystallizing-section corresponds to the first flat portion, a source and a drain are disposed outside of the greater-crystallizing-section, and a grain size in the greater-crystallizing-section is greater than a grain size in the smaller-crystallizing-section;
a second gate insulating layer, disposed on the polycrystalline semiconductor layer; and
an upper gate, disposed on the second gate insulating layer, wherein a length of the upper gate is shorter than a length of the bottom gate.

11. The TFT as claimed in claim 10, wherein the grain size in the greater-crystallizing-section is substantially greater than 0.5 μm.

12. The TFT as claimed in claim 10, wherein the length of the upper gate substantially ranges from 0.3 μm to 1.8 μm, and the length of the bottom gate substantially ranges from 0.5 μm to 2.0 μm.

13. The TFT as claimed in claim 10, further comprising:
a passivation layer, comprising a plurality of contact openings corresponding to the source, the drain, and the upper gate; and
a plurality of contact conductors, formed within the plurality of contact openings, wherein the plurality of contact conductors is electrically connected to the source, the drain, and the upper gate.

14. The TFT as claimed in claim 10, further comprising:
a buffer layer, disposed between the substrate and the bottom gate.

15. A TFT, comprising:
a substrate;
a bottom gate, disposed on the substrate;
an insulating spacer, disposed on a sidewall of the bottom gate;
a first gate insulating layer, disposed on the substrate to cover the bottom gate and the insulating spacer, wherein the first gate insulating layer has a first flat portion, a second flat portion, and a stair portion, the first flat portion is disposed directly above the bottom gate, the second flat portion is disposed above a portion of the substrate which is not covered by the bottom gate and the insulating spacer, and the stair portion is disposed between the first flat portion, the second flat portion, and the insulating spacer;
a polycrystalline semiconductor layer, disposed on the first gate insulating layer above the bottom gate, having a greater-crystallizing-section and smaller-crystallizing-section, wherein the smaller-crystallizing-section corresponds to the stair portion, the greater-crystallizing-section corresponds to the first flat portion, a source and a drain are disposed outside of the greater-crystallizing-section, and a grain size in the greater-crystallizing-section is greater than a grain size in the smaller-crystallizing-section;
a second gate insulating layer, disposed on the polycrystalline semiconductor layer; and
an upper gate, disposed on the second gate insulating layer.

16. The TFT as claimed in claim 15, wherein the grain size in the greater-crystallizing-section is substantially greater than 0.5 μm.

17. The TFT as claimed in claim 15, further comprising:
a passivation layer, comprising a plurality of contact openings corresponding to the source, the drain, and the upper gate; and
a plurality of contact conductors, formed within the plurality of contact openings, wherein the plurality of contact conductors is electrically connected to the source, the drain, and the upper gate.

18. The TFT as claimed in claim 15, further comprising:
a buffer layer, disposed between the substrate and the bottom gate.
